(19) United States
(12) Patent Application Publication
(10) Pub. No.: US 2008/0067612 A1
(43) Pub. Date: Mar. 20, 2008

(54) Semiconductor Device Including Nickel Alloy Silicide Layer Having Uniform Thickness and Method of Manufacturing the Same

(76) Inventors: Sun Jung Lee, Seoul (KR); Bong-seok Suh, Hwaseong-si (KR); Hong-jae Shin, Seoul (KR); Kee-young Jun, Yongin-si (KR); Jung-hoon Lee, Suwon-si (KR)

Correspondence Address: F. CHAU & ASSOCIATES, LLC, 130 WOODBURY ROAD, WOODBURY, NY, 11797, US

(21) Appl. No.: 11/775,089

(22) Filed: Jul. 9, 2007

(30) Foreign Application Priority Data
Jul. 14, 2006 (KR) 10-2006-0066443

(51) Int. Cl. H01L 29/78; H01L 21/336

(52) U.S. Cl. 257/397; 438/296; 257/E29.255; 257/E21.409

(57) ABSTRACT

A semiconductor device including a nickel alloy silicide layer having a uniform thickness includes isolation regions formed in a substrate, gate electrodes respectively formed on the substrate between the isolation regions, source/drain regions respectively formed between the gate electrodes and the isolation regions, spacers formed on lateral surfaces of the gate electrodes, and a nickel alloy silicide layer formed on upper portions of the source/drain regions.

### CROSS REFERENCE TO RELATED APPLICATION

This application claims priority from Korean Patent Application No. 10-2006-0066443 filed on Jul. 14, 2006 in the Korean Intellectual Property Office, the contents of which are herein incorporated by reference in their entirety.

### BACKGROUND OF THE INVENTION

1. Field of the Invention

The present disclosure is directed to a semiconductor device and a method of manufacturing the same, and more particularly, to a semiconductor device including a silicide layer having a uniform thickness and a method of manufacturing the same.

2. Description of the Related Art

With the reduction in the thickness of patterns of highly integrated semiconductor devices having high performance, reduction in the resistance of conductive lines and contacts or vias is attracting attention. For this reason, a known polysilicon conductive line and a contact or via are formed of a metal and a metal silicide layer. When the conductive line is formed of a metal, a silicon substrate is used as a substrate. And, polysilicon is used to form many conductive parts. Therefore, a metal silicide layer needs to he formed at a portion where the metal and silicon are in contact with each other. Hence, a method of forming a metal silicide layer using various metals has been studied. In general, a method of forming a metal layer on a silicon layer using a physical deposition process, for example, sputtering, and then performing a heat treatment to form a metal silicide layer is widely used. In this method, silicon atoms of the silicon layer are thermally diffused into the metal layer and substituted so as to form metal silicide.

Additionally, a method of forming a metal silicide layer using nickel among various metals has been studied. Since nickel is used more to form a fine silicide layer compared with other metals, a method of forming a metal silicide layer using nickel is being studied.

FIGS. 1A and 1B are longitudinal cross-sectional views schematically showing a conventional method of forming a silicide layer of a semiconductor device.

Referring to FIG 1A, isolation regions 110 are formed in a silicon substrate 100, and a nickel layer 120 is formed on the entire surface of the silicon substrate 100 to form a silicide layer. The nickel layer 120 is formed using a sputtering method.

Referring to FIG. 1B, a nickel silicide layer 130 is formed through a heat treatment at a high temperature, and a portion of the nickel layer 120 that does not undergo a silicide reaction is removed. Nickel atoms of the nickel layer 120 are thermally diffused into the silicon substrate 100 at a high temperature so as to form the nickel silicide layer 130. At this time, the nickel atoms of the nickel layer 120 formed on an active region of the silicon substrate 100 and the nickel atoms of the nickel layer 120 formed on the isolation regions 110 are diffused into the silicon substrate 100, which results in a thick silicide layer A at portions of the nickel silicide layer that are close to the isolation regions 110. The thick nickel silicide layer A increases a leakage current. Accordingly, a method of forming a nickel silicide layer having a uniform thickness is desired.

### SUMMARY OF THE INVENTION

According to an aspect of the invention, there is provided a semiconductor device including isolation regions formed in a substrate, gate electrodes respectively formed on the substrate between the isolation regions, source/drain regions respectively formed between the gate electrodes and the isolation regions, spacers formed on lateral surfaces of the gate electrodes, and a nickel alloy silicide layer formed on upper portions of the source/drain regions.

The source/drain regions may be SiGe regions.

The nickel alloy silicide layer may be formed to have the same height as a surface of the substrate.

The semiconductor device may further include a nickel alloy silicide layer formed on upper portions of the gate electrodes.

A nickel alloy may be an alloy of nickel and any one of platinum, titanium, cobalt, palladium, iridium, ruthenium, tungsten, tantalum, and vanadium.

The semiconductor device may further include a silicon oxide film formed between the gate electrodes and the spacers.

According to another aspect of the invention, there is provided a method of manufacturing a semiconductor device, the method including forming isolation regions in a substrate, forming gate electrodes on the substrate, forming first impurity injection regions in the substrate, forming spacers on lateral surfaces of the gate electrodes, forming second impurity injection regions in the substrate, removing an exposed butter film to expose upper surfaces of the gate electrodes and surfaces of the first and second impurity injection regions, selectively forming a nickel layer on the exposed upper surfaces of the gate electrodes and the surfaces of the first and second impurity injection regions, forming a metal layer on a surface of the nickel layer, and performing a heat treatment so as to form a nickel alloy silicide layer on the upper surfaces of the gate electrode and the surfaces of the first and second impurity injection regions.

The first impurity injection regions may have a first concentration, a first depth, and a first width, and the second impurity injection regions may have a second concentration higher than the first concentration, a second depth larger than the first depth, and a second width smaller than the first width.

The nickel layer may be formed using an electroless plating method, and the metal layer may be formed of any one of platinum, titanium, cobalt, palladium, iridium, ruthenium, tungsten, tantalum, and vanadium.

The metal layer may be formed of 3 to 15% by atoms of the nickel layer.

The substrate of the first and second impurity injection regions may be a substrate containing SiGe.

The forming of the spacers may include forming the boiler film on the surfaces of the gate electrodes, forming a mask layer on the buffer film, and patterning the mask layer.

The temperature of the heat treatment may be 300 to 600° C., and the heat treatment time may be 3 minutes or less.

The gate electrodes may be formed of polysilicon, the buffer film may be formed of a silicon oxide film, and the mask layer may be formed of a silicon nitride film.

According to another aspect of the invention, there is provided a method of manufacturing a semiconductor device, the method including forming isolation regions in a substrate, forming gate electrodes on the substrate, forming spacers on lateral surfaces of the gate electrodes, forming source/drain regions in the substrate, selectively forming a nickel alloy layer on upper surfaces of the gate electrodes and surfaces of source/drain regions, and performing a heat treatment so as to form a nickel alloy silicide layer on the upper surfaces of the gate electrodes and the surfaces of the source/drain regions.

The source/drain regions may be formed using a first impurity injection process that is performed, with a first concentration, a first depth, and a first width, and a second impurity injection process that is performed with a second concentration higher than the first concentration, a second depth larger than the first depth, and a second width smaller than the first width.

The nickel alloy layer may be formed using an electroless plating process, and may be formed of an alloy of nickel and any one of platinum, titanium, cobalt, palladium, iridium, ruthenium, tungsten, tantalum, and vanadium.

The electroless plating process may be performed using a plating solution that contains a nickel compound, has a pH concentration of 6 or more, and contains 30% by atoms or less of metal atoms for forming an alloy with respect to nickel atoms.

The temperature of the heat treatment may be 300 to 600° C., and the heat treatment time may be 3 minutes or less.

The gate electrodes may be formed of polysilicon, the buffer film may be formed of a silicon oxide film, and the mask layer may be formed of a silicon nitride film.

### BRIEF DESCRIPTION OF THE DRAWINGS

The above and other features of the present invention will become more apparent by describing in detail exemplary embodiments thereof with reference to the attached drawings.

FIGS. 1A and 1B are longitudinal cross-sectional views schematically showing a conventional method of forming a nickel silicide layer of a semiconductor device.

FIGS. 2A and 2B are longitudinal cross-sectional views schematically showing a semiconductor device including a nickel silicide layer having a uniform thickness according to an embodiment of the invention.

FIGS. 3A to 3G are longitudinal cross-sectional views showing a method of manufacturing a semiconductor device including a nickel silicide layer having a uniform thickness according to an embodiment of the invention.

FIGS. 4A and 4B are graphs illustrating showing a heat treatment in the method of manufacturing a semiconductor device according to an embodiment of the invention.

### DESCRIPTION OF EXEMPLARY EMBODIMENTS

Advantages and features of the present invention and methods of accomplishing the same may be understood more readily by reference to the following detailed description of exemplary embodiments and the accompanying drawings. The present invention may, however, be embodied in many different forms and should not be construed as being limited to the embodiments set forth herein. Like reference numerals refer to like elements throughout the specification.

Accordingly, the embodiments of the invention are not intended to limit the scope of the present invention but cover all changes and modifications that can be caused by a change in a manufacturing process. Hereinafter, a semiconductor device according to an embodiment of the invention and a method of manufacturing the same will be described in detail with reference to the drawings.

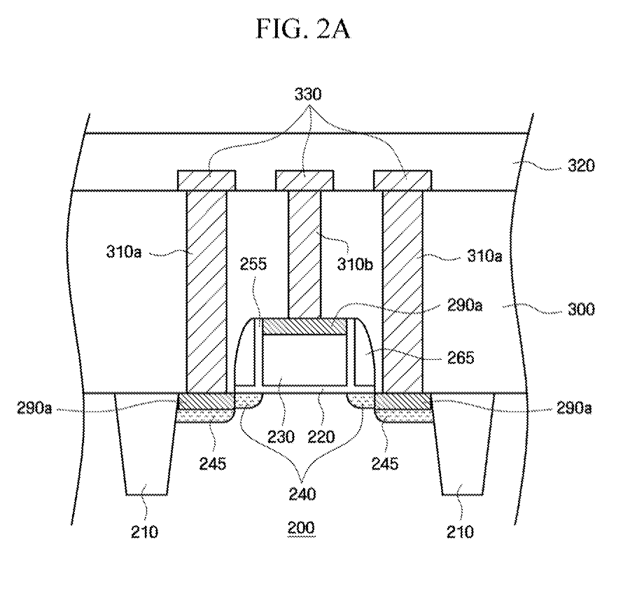

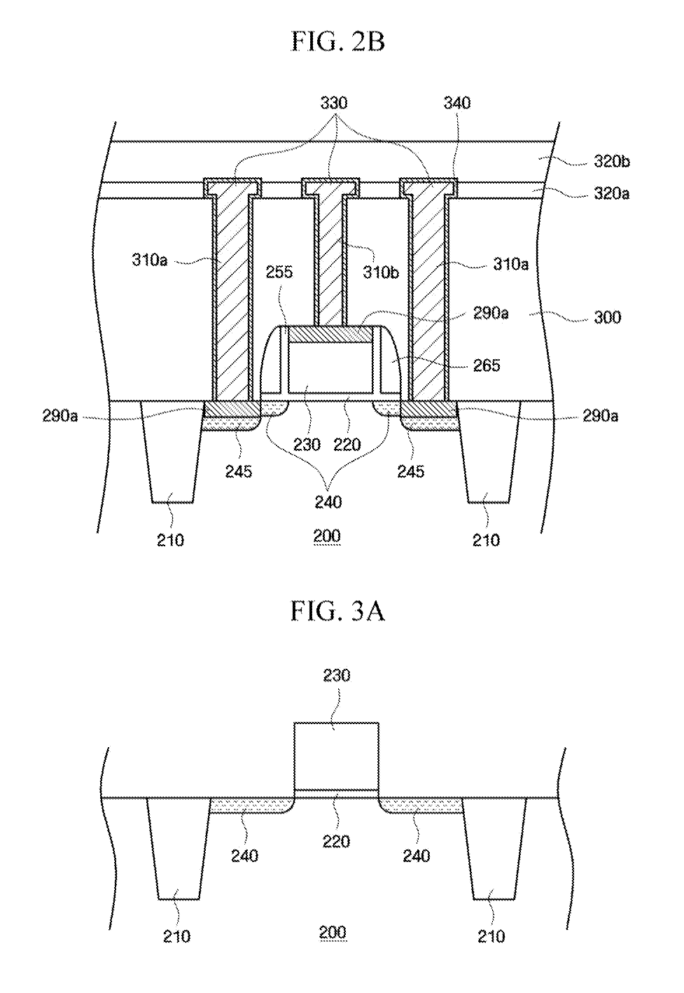

FIGS. 2A and 2B are longitudinal cross-sectional views schematically showing a semiconductor device according to an embodiment of the invention.

Referring to FIG. 2A, a semiconductor device according to the embodiment of the invention includes isolation regions 210 formed in a substrate 200, gate electrodes 230 that are formed on the substrate 200 to be insulated from the substrate 200 by an insulating film 220 and to be respectively disposed between the isolation regions 210, source/drain regions 240 and 245 respectively formed in the substrate 200 between the gate electrodes 230 and the isolation regions 210, spacers 265 formed on lateral surfaces of the gate electrodes 230, and a nickel alloy silicide layer 290a formed on upper portions of the source/drain regions 240 and 245.

The substrate 200 may be, for example, a silicon (Si) substrate. Alternatively, the substrate may be an SOI (silicon on insulator), an SOS (silicon on sapphire), or a compound semiconductor substrate.

Particularly, the source/drain regions may be SiGe regions. The SiGe regions may be regions formed on the surface of the silicon substrate corresponding to the source/drain using a deposition or growth method.

The nickel alloy silicide layer 290a may be formed so as to have a substantially uniform thickness. Since the nickel alloy silicide layer 290a according to the embodiment of the invention may be formed using a selective electroless plating method, instead of a physical deposition method, the thickness may be substantially uniform. The detailed description thereof will be given below.

A nickel alloy may be an alloy of nickel and any one of platinum, titanium, cobalt, palladium, iridium, ruthenium, tungsten, tantalum, and vanadium. The formation of the nickel alloy will be described below.

A silicon oxide film 255 may be further formed between the gate electrodes 230 and the spacers 265. In this embodiment, the gate electrodes 230 may be formed of polycrystalline silicon. The silicon oxide film 255 may be formed on the surface of the substrate 200 and the surfaces of the gate electrodes 230 before the formation of the spacers 265, to thereby serve as a buffer. In this embodiment, the spacers 265 may be formed of a silicon nitride film. Generally, polycrystalline silicon and the silicon nitride film have poor interface properties due to different thermal expansion rates. The silicon oxide film 255 is formed between the gate electrodes and the spacers so as to improve the interface properties of the polycrystalline silicon and the silicon nitride film. Additionally, upon the formation of the spacers 265, the silicon oxide film remains on the upper portions of the gate electrodes 230 so as to prevent the upper surfaces of the gate electrodes 230 from being damaged due to plasma.

After the nickel alloy silicide layer 290a is formed, an interlayer insulating film 300 is formed, and plugs 310a, 310b are formed to vertically pass through the interlayer insulating film 300 to be connected to the nickel alloy silicide layer 290a. The interlayer insulating film 300 may be a silicon oxide film, and the plugs 310a, 310b may be formed of metals.

Wiring lines 330 may be formed on the interlayer insulating film 300 so as to be connected to the plugs 310a, 310b. The wiring lines 330 may be further formed on the interlayer insulating film 300. The wiring lines 330 may be connected to the plugs 310a, 310b and the widths of the wiring lines 330 may be larger than those of the plugs 310a, 310b. The wiring lines 330 may be formed of metals, such as tungsten, copper, and aluminum.

A capping layer 320 may be formed on the interlayer insulating film 300 to cover the wiring lines 330. The capping layer 320 may be formed of a silicon oxide film or a silicon nitride film.

Referring to FIG 2B, in a semiconductor device according to another embodiment of the invention, a barrier layer 340 formed of a silicon nitride film or a metal film containing Ti or TiN may be further formed at interfaces of the plugs 310a, 310b and the interlayer insulating film 300, unlike the semiconductor device according to the embodiment of the invention shown in FIG 2A. In case of the silicon nitride film, a chemical vapor deposition method may be used. In case of the metal film containing Ti or TiN, a physical deposition method or a chemical vapor deposition method may be used. When the barrier layer 340 is formed of a metal, a plating method may be used In this case, any of an electrolyte plating method and an electroless plating method may be used.

Additionally, the barrier layer 340 may be formed at interfaces of the wiring lines 330 and the interlayer insulating film 300. That is, when the plugs 310a, 310b and the wiring lines 330 are formed using a damascene method, the barrier layer 340 may be formed as shown in FIG 2B.

When the plugs 310a, 310b and the barrier layer 340 are formed of metals using different processes, an additional barrier layer, which is not shown in FIG. 2B, may be formed at interfaces of the plugs 310 and the barrier layer 340.

The capping layer 320 on the interlayer insulating film 300 may include a first capping layer 320a that has the same height as the wiring lines 330 and a second capping layer 320b that covers the wiring lines 330. The first capping layer 320a and the second capping layer 320b may be formed of silicon nitride films or silicon oxide films. When the first capping layer 320a is formed of the silicon oxide film, the silicon nitride film may be further formed between the interlayer insulating film 300 and the first capping layer 320a. The silicon nitride film may be formed below the wiring lines 330. That is, the wiring lines 330 may be formed on the silicon nitride film that is formed on the interlayer insulating film 300.

The barrier layer 340 formed on the wiring lines 330 may be provided at a position higher than the first capping layer 320a.

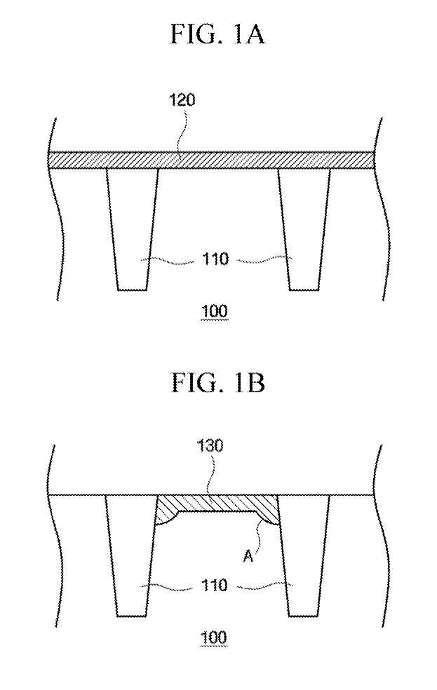

The semiconductor devices according to the embodiments of the invention shown in FIGS. 2A and 2B may be cell regions of the semiconductor devices and in particular, memory devices. When the semiconductor devices are not cell regions but peripheral circuit regions, since the widths of impurity-doped regions 240 and 245 are relatively large, the silicide regions may rarely affect on the operation of the device even though the silicide regions are made thick as shown in FIG. 1B. In this case, the peripheral circuit regions may be a silicide layer (for example, tungsten silicide, cobalt silicide, and titanium silicide) that is formed through the diffusion of silicon.

A method of manufacturing a semiconductor device according to the embodiment of the invention will be described with reference to the drawings.

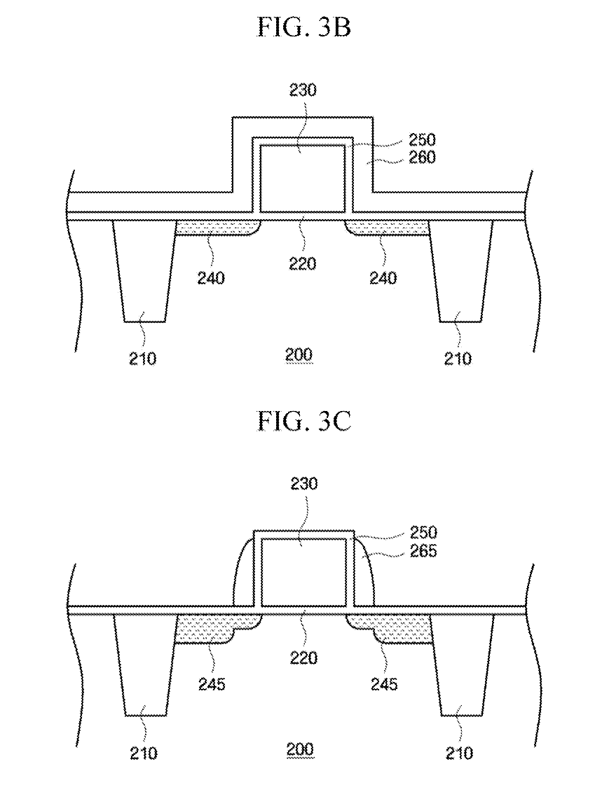

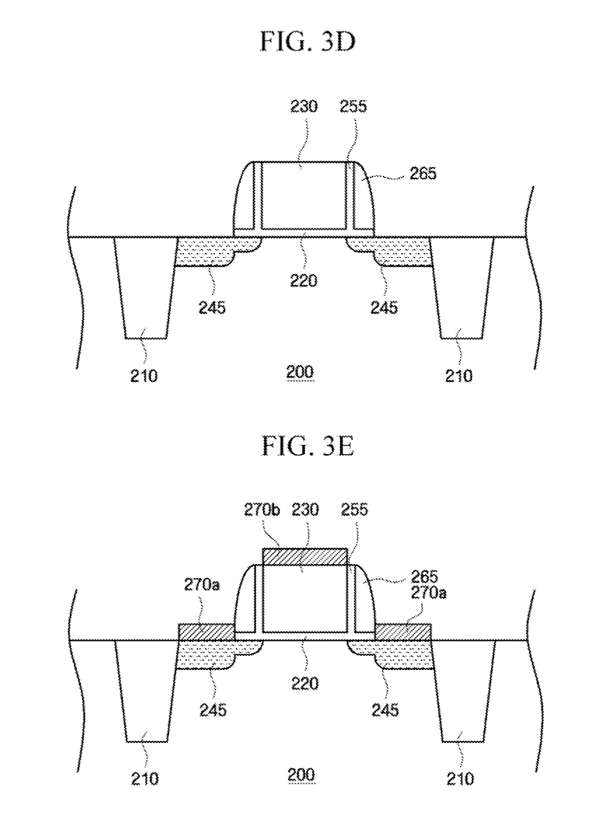

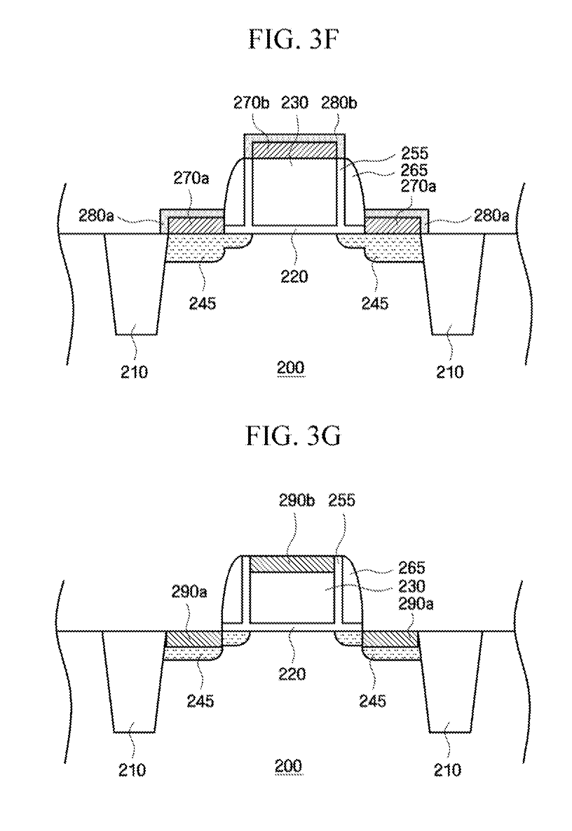

FIGS. 3A to 3G are longitudinal cross-sectional views schematically showing a method of manufacturing a semiconductor device according to an embodiment of the invention.

Referring to FIG. 3A, the isolation regions 210 are formed in the substrate 200, then the sate insulating film 220 and the gate electrodes 230 are formed, and subsequently first source/drain regions 240 are formed. The substrate 200 may be, for example, a silicon (Si) substrate. Alternatively, the substrate may be an SOI (silicon on insulator), an SOS (silicon on sapphire), or a compound semiconductor substrate.

The isolation regions 210 may be formed using, for example, a shallow trench isolation (STI) method.

In this embodiment, for example, the gate insulating film 220 may be formed of a silicon oxide film and the gate electrodes 230 may be formed of polycrystalline silicon.

The first source/drain regions 240 may be source/drain regions or low concentration impurity injection regions of a transistor. In this embodiment, in the semiconductor device, an impurity is injected twice or more so as to form the source/drain regions of the transistor. First, the impurity is injected with a relatively low concentration. Next, the impurity is injected with a relatively high concentration. That is, the first source/drain regions may be regions into which the impurity is injected with a relatively lower concentration compared with second source/drain regions 245 as described below. The impurity may be a group III or V element. When a group III element is injected as the impurity, boron (B) ions may be injected. When a group V element is injected as the impurity, phosphorous (P) ions or arsenic (As) ions may be injected as the impurity. In this embodiment, the arsenic ions are injected as the impurity with a concentration of 2.5E15, for example. Note that the process conditions presented herein are for illustrative purposes only and are not to be construed to limit the scope of invention.

In this embodiment, the entire source/drain regions or specified portions, for example, PMOS regions, may be SiGe regions. The SiGe regions may be formed by exposing the silicon substrate and selectively performing a deposition or growth method. In this case, after the exposed silicon substrate is etched so as to reduce the height, of the surface thereof, SiGe may be deposited or grown, such that the SiGe regions may be formed to have the original surface height.

Referring to FIG. 3B, the butler film 250 is entirely formed and the mask layer 260 is formed on the entire surface of the buffer film 250. For example, in this embodiment, the buffer film 250 may be a silicon oxide film and the mask layer 260 may be a silicon nitride film. For example, the buffer film may be formed to have a thickness of 50 to 150 Å, and the mask layer 260 may be formed to have a thickness of 100 to 500 Å. The buffer film 250 may be formed using an oxidation or deposition method, and the mask layer 260 may be formed using a deposition method.

Referring to FIG 3C, the spacers 265 are formed on both lateral surfaces of the gate electrodes 230, and then the second source/drain regions 245 are formed. The mask layer 260 may be dry-etched so as to form the spacers 265. In this embodiment, the mask layer 260 may be formed of a silicon nitride film. The second source/drain regions 245 may be regions into which the impurity is injected with a relatively high concentration compared with the first source/drain regions 240. In this embodiment, the concentration of the impurity in the second source/drain regions may be two times as much as that of the impurity in the first source/drain regions. Further, the second source/drain regions 245 may be narrower and deeper than the first source/drain regions 240. To form the second source/drain regions 245, the impurity ions of the same group as the first source/drain regions 240 may be injected. In detail, when B ions are injected to form the first source/drain regions 240, the B ions may also be injected to form the second source/drain regions. When As ions are injected to form the first source/drain regions, the As ions may also be injected to form the second source/drain regions. Further, when the As ions are injected to form the first source/drain regions 240, P ions or As and B ions may be injected to form the second source/drain regions. In this embodiment, for example, the As ions may be injected in a concentration of 5.0E15, or the P ions may be further injected in a concentration of 2.0E1.3 to form the second source/drain regions. Since the spacers 265 can serve as an ion injection mask, the second source/drain regions 245 may be aligned with the spacers 265. Additionally, impurity ions may be injected onto the upper portions of the gate electrodes 230, which are not shown in FIG 3C. The buffer film 250 that is formed on the surfaces of the impurity regions 240 and 245 and on the surfaces of the gate electrodes 230 may serve as a protective film for protecting the surfaces of the impurity regions 240 and 245 and the surfaces of the gate electrodes 230 during the ion injection.

Referring to FIG. 3D, the patterned buffer film 255 that is exposed at the upper surfaces of the gate electrodes 230 and the impurity regions 240 and 245 is removed to expose the upper surfaces of the gate electrodes 230 and the surfaces of the impurity regions 240 and 245. In this embodiment, the exposed portions of the buffer film 250 may be removed to form the patterned buffer film 255 using, for example, diluted fluoric acid. Alternatively, the exposed portions of the buffer film 250 may be removed using a dry etching method. When the exposed portions of the buffer film 250 is removed using diluted fluoric acid, it is possible to prevent the surfaces of the gate electrodes 230 and the surfaces of the source/drain regions 240 and 245 from being damaged by plasma.

Referring to FIG. 3E, an electroless nickel plating process is performed so as to selectively form nickel layers 270a and 270b on the exposed surfaces of the gate electrodes 230 and the source/drain regions 240 and 245 In this embodiment, the nickel layers 270a and 270b are formed using the electroless plating method, in which the substrate is immersed in a plating solution containing a nickel compound, such as nickel chloride (NiCl₂) or nickel sulfate (NiSO₄), instead of a physical deposition method. In this embodiment, the plating solution may have the pH of 6 or more. Particularly, the plating solution having the pH of 10 may be used. Additionally, in this embodiment, the nickel layers may have a thickness of about 200 Å to exemplarily implement the technical idea of the invention. However, the nickel layers 270a and 270b may have various thicknesses according to characteristics of the device, and this embodiment is not intended to limit the invention.

Referring to FIG 3F, metal layers 280a and 280b are formed on the surfaces of the nickel layers 270a and 270b. The metal layers 280a and 280b may be formed using an electroless plating process. The metal layers 280a and 280b may be formed of any one of platinum, titanium, cobalt, palladium, iridium, ruthenium, tungsten, tantalum, and vanadium. In this embodiment, platinum, cobalt, and vanadium are selected.

Further, in this embodiment, as shown in FIG. 3F, the nickel layers 270a and 270b are formed and the metal layers 280a and 280b are then formed on the nickel layers 270a and 270b. Alternatively, in another embodiment of the invention, the nickel layers 270a and 270b and the metal layers 280a and 280b may be formed at the same time. That is, a nickel alloy layer may be formed. This process may be performed by adding metal elements to the plating solution used in the electroless plating process. In another embodiment of the invention, atoms of any one of platinum, titanium, cobalt, palladium, iridium, ruthenium, tungsten, tantalum, and vanadium are added to the plating solution to perform the electroless plating process, thereby forming the nickel alloy layer

When the nickel layers 270a and 270b and the metal layers 280a and 280b are separately formed, the metal layers may be formed of 5 to 15 atomic % of the nickel layers. Since the metal layers 280a and 280b have various atom intervals according to the type thereof, it is undesirable to compare the metal layers 280a and 280b with the nickel layers 270a and 270b in view of thickness. A relative atomic ratio of nickel and another metal may be a meaningful factor in the formation of the nickel alloy layer, in this case, the plating process for forming the nickel layers 270a and 270b and the plating process for forming the metal layers 280a and 280b may be separately performed.

In another embodiment, when nickel and a metal for an alloy are simultaneously formed, metal atoms for an alloy may be added to the plating solution in the amount of 5 to 1.5% by atoms with respect to the nickel atoms.

Referring to FIG. 3G, a heat treatment process is performed to form nickel alloy silicide layers 290a and 290b. In detail, the nickel layers 270a and 270b and the metal layers 280a and 280b are formed and then heated at a high temperature, for example, 300 to 600° C., to cause the nickel atom to be diffused into the upper portions of the gate electrodes 230 and the upper portions of the source/drain regions 240 and 245, thereby forming the nickel alloy silicide layers 290a and 290b.

When the nickel alloy silicide layer according to this embodiment is formed, it is possible to obtain a silicide layer having desirable properties compared with a case where only one of the metal layers, such as the nickel layer, is formed to form the silicide layer. When the silicide layer is formed using a single metal layer, such as a nickel layer, the silicide layer may be bonded to an oxide film or the impurity, such as oxygen, locally formed on the surface of the substrate surface, which causes an increase in resistance. An exemplary metal layer is formed on the nickel layer to react the metal with oxygen or the like, thereby reducing the resistance. That is, the metal that is formed on the nickel layer has desirable conductivity even though the metal is oxidized.

Subsequently, various processes are performed to manufacture the semiconductor devices according to embodiments of the invention shown in FIGS. 2A and 2B.

The subsequent processes include a process of forming the interlayer insulating film 300, a process of forming via holes to vertically pass through the interlayer insulating film 300 so as to be then connected to the silicide layer 290, a process of plugging the via holes with a conductive material to form the plugs 310a, 310b, a process of forming the barrier layer 340 at the walls of the via holes, a process of forming the capping layer 320, a process of forming the wiring lines 330, a process of forming the barrier layer 340 at the walls of the wiring lines 330, and a damascene process of simultaneously forming the wiring lines 330 and the plugs 310, which may be selectively performed.

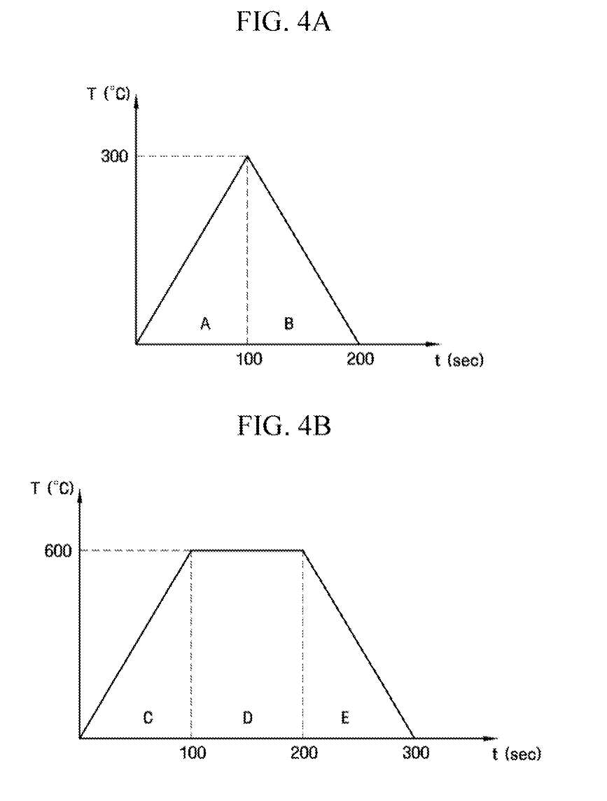

FIGS. 4A and 4B are graphs illustrating a heat treatment in a method of manufacturing a semiconductor device according to the embodiment of the invention.

Referring to FIG. 4A, the semiconductor substrate on which the nickel alloy silicide layer is to be formed is put in a chamber for a heat treatment. Next, the temperature in the chamber is increased at a constant heating rate to the maximum temperature and then decreased during the heat treatment. For example, when the heat treatment is performed at the maximum temperature of 300° C. for 200 seconds, the temperature in the chamber is increased for a predetermined time (A) and then decreased for a residual time (B). FIG. 4A illustrates an embodiment of the invention. The maximum temperature may be set according to various embodiments, and the heat treatment time (A and B) may vary. Additionally, the time (A) that is required to increase the temperature in the chamber and the time (B) that is required to decrease the temperature do not need to be identical to each other. That is, the time (A) that is required to increase the temperature in the chamber and the time (B) that is required to decrease the temperature may be set to be different from each other.

Referring to FIG. 4B, the semiconductor substrate on which the nickel alloy silicide layer is to be formed is put in the chamber for the heat treatment. Next, the temperature in the chamber is rapidly increased to the maximum temperature, then maintained at that temperature for a predetermined time, and subsequently decreased. For example, after the maximum temperature is set to 600° C., the temperature in the chamber is increased (C), then maintained at that temperature (D), and subsequently decreased (E). Similarly, the time (C, D, and E) may be set separately from one another.

Although the present invention has been described in connection with the exemplary embodiments of the present invention, it will be apparent to those skilled in the art that various modifications and changes may be made thereto without departing from the scope and spirit of the invention. Therefore, it should be understood that the above embodiments are not limitative, but illustrative in all aspects.

As described above, according to the semiconductor devices and the methods of manufacturing the semiconductor devices of the embodiments of the invention, it is possible to form a nickel alloy silicide layer having a uniform thickness. Therefore, leakage current and contact resistance are low, and thus a semiconductor device having improved performance can be obtained.

What is claimed is:

1. A semiconductor device comprising:
isolation regions formed in a substrate;
gate electrodes respectively formed on the substrate between the isolation regions;
source/drain regions respectively formed between the gate electrodes and the isolation regions;
spacers formed on lateral surfaces of the gate electrodes; and
a nickel alloy silicide layer formed on upper portions of the source/drain regions.

2. The semiconductor device of claim 1, wherein the source/drain regions are SiGe regions.

3. The semiconductor device of claim 1, wherein the nickel alloy silicide layer has the same height as the surface of the substrate.

4. The semiconductor device of claim 1, further comprising a nickel alloy silicide layer formed on upper portions of the gate electrodes.

5. The semiconductor device of claim 1, wherein a nickel alloy is an alloy of nickel and any one of platinum, titanium, cobalt, palladium, iridium, ruthenium, tungsten, tantalum, and vanadium.

6. The semiconductor device of claim 1, further comprising a silicon oxide film formed between the gate electrodes and the spacers.

7. A method of manufacturing a semiconductor device, the method comprising:
forming isolation regions in a substrate;
forming gate electrodes on the substrate;
forming first impurity injection regions in the substrate;
forming spacers on lateral surfaces of the gate electrodes;
forming second impurity injection regions in the substrate;
removing an exposed buffer film to expose upper surfaces of the gate electrodes and surfaces of the first and second impurity injection regions;
selectively forming a nickel layer on the exposed upper surfaces of the gate electrodes and the surfaces of the first and second impurity injection regions;
forming a metal layer on a surface of the nickel layer; and
performing a heat treatment to form a nickel alloy silicide layer on upper portions of the gate electrodes and upper portions of the first and second impurity injection regions.

8. The method of claim 7, wherein the first impurity injection regions are formed with a first concentration, a first depth, and a first width, and the second impurity injection regions are formed with a second concentration higher than the first concentration, a second depth larger than the first depth, and a second width smaller than the first width.

9. The method of claim 7, wherein the nickel layer is formed using an electroless plating method.

10. The method of claim 9, wherein the metal layer is formed of any one of platinum, titanium, cobalt, palladium, iridium, ruthenium, tungsten, tantalum, and vanadium.

11. The method of claim 9, wherein the electroless plating method is performed using a plating solution that contains a nickel compound and has a pH concentration of 6 or more.

12. The method of claim 7, wherein the metal layer is formed of 3 to 15% by atoms with respect to the nickel layer.

13. The method of claim 7, wherein the impurity first and second injection regions contain SiGe.

14. The method of claim 7, wherein the forming of the spacers comprises:
forming a buffer film on the surfaces of the gate electrodes;
forming a mask layer on the buffer film; and
patterning the mask layer to form the spacers,

15. A method of manufacturing a semi conductor device, the method comprising:
forming isolation regions in a substrate;
forming gate electrodes on the substrate;
forming spacers on lateral surfaces of the gate electrodes,
forming source/drain regions in the substrate;
selectively forming a nickel alloy layer on upper surfaces of the gate electrodes and surfaces of source/drain regions; and
performing a heat treatment to form a nickel alloy silicide layer on the upper surfaces of the gate electrodes and the surfaces of the source/drain regions.

16. The method of claim 15, wherein the source/drain regions are formed using a first impurity injection process that is performed with a first concentration, a first depth, and a first width, and a second impurity injection process that is performed with a second concentration higher than the first concentration, a second depth larger than the first depth, and a second width smaller than the first width.

17. The method of claim 15, wherein the nickel alloy layer is formed using an electroless plating process.

18. The method of claim 17, wherein the nickel alloy layer is formed of an alloy of nickel and any one of platinum, titanium, cobalt, palladium, iridium, ruthenium, tungsten, tantalum, and vanadium.

19. The method of claim 17, wherein the electroless plating process is performed using a plating solution that contains a nickel compound, has a pH concentration of 6 or more, and contains 30% by atoms or less of metal atoms for forming an alloy with respect to nickel atoms.

20. The method of claim 15, wherein the substrate of the impurity injection regions contains SiGe.
